(19) United States
(12) Patent Application Publication
(10) Pub. No.: US 2005/0224921 A1
(43) Pub. Date: Oct. 13, 2005

(54) Method for bonding wafers to produce stacked integrated circuits

(76) Inventors: Subhash Gupta, Singapore (SG); Paul Kwok Keung Ho, Singapore (SG); Sangki Hong, Singapore (SG)

Correspondence Address: The Law Offices of Calvin B. Ward;Suite 305, 18 Crow Canyon Court, San Ramon, CA, 94583, US

(21) Appl. No.: 11/150,879

(22) Filed: Jun. 9, 2005

Related U.S. Application Data
(62) Division of application No. 09/847,667, filed on May 1, 2001, now abandoned.

(51) Int. Cl. H01L 29/40; H01L 21/461

(52) U.S. Cl. 257/621; 257/686; 438/459; 438/692

(57) ABSTRACT

An integrated circuit wafer element and an improved method for bonding the same to produce a stacked integrated circuit. An integrated circuit wafer according to the present invention includes a substrate having first and second surfaces constructed from a wafer material, the first surface having a circuit layer that includes integrated circuit elements constructed thereon. A plurality of vias extend from the first surface through the circuit layer and terminate in the substrate at a first distance from the first surface. The vias include a stop layer located in the bottom of each via constructed from a stop material that is more resistant to chemical/mechanical polishing (CMP) than the wafer material. The vias may be filled with an electrically conducting material to provide vertical connections between the various circuit layers in a stacked integrated circuit. In this case, the electrical conducting vias are also connected to various circuit elements by metallic conductors disposed in a dielectric layer that covers the circuit layer. A plurality of bonding pads are provided on one surface of the integrated circuit wafer. These pads may be part of the vias. These pads preferably extend above the surface of the integrated circuit wafer. A stacked integrated circuit according to the present invention is constructed by bonding two integrated circuit wafers together utilizing the bonding pads. One of the integrated circuit wafers is then thinned to a predetermined thickness determined by the depth of the vias by chemical/mechanical polishing (CMP) of the surface of that integrated circuit wafer that is not bonded to the other integrated circuit wafer, the stop layer in the vias preventing the CMP from removing wafer material that is within the first distance from the first surface of the substrate of the wafer being thinned.

### FIELD OF THE INVENTION

The present invention relates to integrated circuits, and more particularly, to a method for bonding wafers together to form integrated circuits having a stack of thin layers.

### BACKGROUND OF THE INVENTION

Modem integrated circuits are typically constructed in a thin layer in a semiconducting layer on a substrate wafer such as silicon. This essentially two-dimensional structure limits both the size of the integrated circuit and the speed at which the circuit operates. The speed at which an integrated circuit operates is determined by the distance between the farthest separated components that must communicate with one another on the chip. For any given number of components, the path lengths will, in general, be significantly reduced if the circuit can be laid out as a three dimensional structure consisting of a number of vertically-stacked layers of circuitry, provided the vertical distances between the layers are much smaller than the width of the chips that make up the individual layers.

One promising scheme for providing such stacked structures utilizes a method for stacking and bonding entire wafers. In this method, integrated circuits are fabricated on conventional wafers. Two wafers are bonded vertically by thinning one wafer in a first coarse thinning operation by removing material from the back of the wafer. The circuitry on the front surface of each wafer is covered with an insulating layer having metal filled vias that make contact with the underlying circuitry and act as electrical connection points between the two wafers. The front surfaces of the wafers are then placed in contact with one another and bonded via thermal diffusion bonding. One of the wafers is then further thinned to a thickness of a few microns by etching or mechanically grinding the back surface of that wafer further. Once the wafer has been thinned, a new set of vias is opened in the backside and filled with metal to provide the connection points for adding yet another wafer to the stack. The process is then repeated until the desired number of layers has been bonded to form the three-dimensional stack. The three-dimensional stack is then cut into three-dimensional chips and packaged.

This process requires that the second wafer thinning operation generate a layer that is uniform in thickness over the entire 8 to 12 inch wafer to a precision of a fraction of a micron. If the process does not provide a precise planar boundary on which to bond the next layer, the next layer will not properly bond. In addition, any significant thickness variations across the thinned layer will result in mis-alignment of the vias, which, in turn, will decrease the overall yield and raise the cost of the devices.

In addition, the alignment of the masks needed to construct the new set of vias from the backside of the thinned wafer presents problems. There are no fiduciary marks on the backside of the thinned wafer. Hence, precise alignment of the masks that define the locations of the vias with respect to the circuitry on the front side of the wafer is difficult.

Broadly, it is the object of the present invention to provide an improved method for stacking and thinning wafers to generate a three-dimensional integrated circuit.

It is a further object of the present invention to provide a method that provides precise control of the thinning process so as to generate layers that have more boundaries that are more nearly parallel than those obtained by prior art methods.

These and other objects of the present invention will become apparent to those skilled in the art from the following detailed description of the invention and the accompanying drawings.

### SUMMARY OF THE INVENTION

The present invention is an integrated circuit wafer element and an improved method for bonding the same to produce a stacked integrated circuit. An integrated circuit wafer according to the present invention includes a substrate having first and second surfaces constructed from a wafer material, the first surface having a circuit layer that includes integrated circuit elements constructed thereon. A plurality of vias extend from the first surface through the circuit layer and terminate in the substrate at a first distance from the first surface. The vias include a stop layer located in the bottom of each via constructed from a stop material that is more resistant to removal by chemical/mechanical polishing (CMP) and/or etch chemistries than the wafer material. For silicon based wafers, the stop layer may be constructed from multiple layers of materials that include insulating and conducting layers to provide chemical or mechanical resistance during etch and CMP. The conducting layer is selected so as to provide a diffusion barrier and mechanical resistance during the CMP process. The vias may be filled with an electrically conducting material to provide vertical connections between the various circuit layers in a stacked integrated circuit. In this case, the electrical conducting vias are also connected to various circuit elements by metallic conductors disposed in a dielectric layer that covers the circuit layer. A plurality of bonding pads are provided on one surface of the integrated circuit wafer. These pads may be part of the vias. These pads preferably extend above the surface of the integrated circuit wafer. A stacked integrated circuit according to the present invention is constructed by bonding two integrated circuit wafers together utilizing the bonding pads. One of the integrated circuit wafers is then thinned to a predetermined thickness determined by the depth of the vias, preferably by chemical/mechanical polishing (CMP) and/or a wet/dry etch process, or a combination thereof, of the surface of that integrated circuit wafer that is not bonded to the other integrated circuit wafer, the stop layer in the vias preventing the CMP from removing wafer material that is within the first distance from the first surface of the substrate of the wafer being thinned.

### BRIEF DESCRIPTION OF THE DRAWINGS

FIG. 1 is a cross-sectional view of a portion of a stacked integrated circuit 10 according to the present invention having a base component layer 20 and two stacked component layers shown at 30 and 40.

FIG. 2 is a cross-sectional view of a wafer 100 used as a starting point for a component layer.

FIG. 3 is a cross-sectional view of wafer 100 after a via 120 has been etched through the dielectric layers and into substrate 110.

FIG. 4 is a cross-sectional view of wafer 100 after via 120 has been lined with two layers.

FIG. 5 is a cross-sectional view of wafer 100 after a trench 128 has been etched in dielectric layer 116.

FIG. 6 illustrates a copper pad that is flush with the surrounding dielectric.

FIG. 7 is a cross-sectional view of a completed component layer element 135.

FIG. 8 is a cross-sectional view of a base component layer element 201 positioned relative to a component layer element 202 that is to be bonded to element 201.

FIG. 9 is a cross-sectional view of the component layers after component layer element 202 has been thinned.

FIG. 10 illustrates the creation of a new set of connection pads on the thinned side of the substrate in component element 202 to continue the stacking process.

FIG. 11 is the final two-layered device as shown at 250.

### DETAILED DESCRIPTION OF THE INVENTION

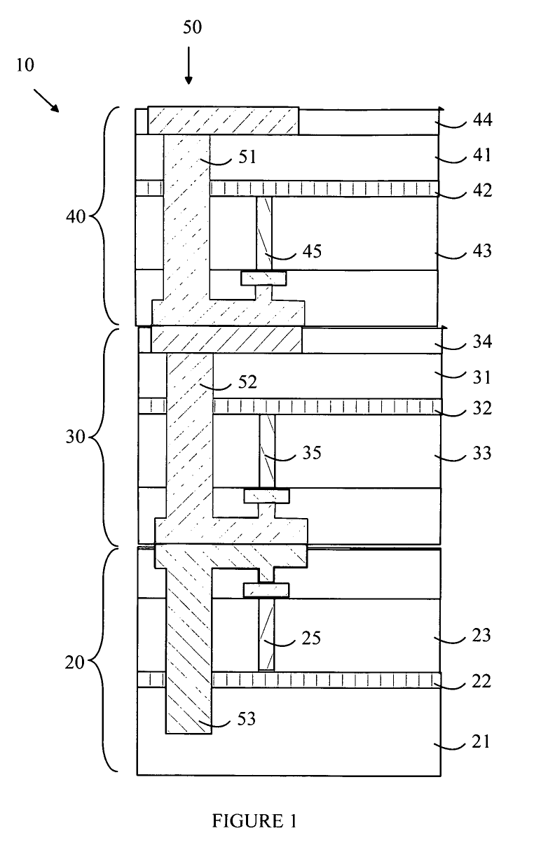

The manner in which the present invention provides its advantages may be more easily understood with reference to FIG. 1 which is a cross-sectional view of a portion of a stacked integrated circuit 10 according to the present invention having a base component layer 20 and two stacked component layers shown at 30 and 40. Each component layer includes an integrated circuit layer that is constructed on a substrate using conventional integrated circuit fabrication techniques. To simplify the following discussion, it will be assumed that the integrated circuit layer is constructed on a conventional silicon substrate in the form of a wafer. The integrated circuit layers corresponding to component layers 20, 30, and 40 are shown at 22, 32, and 42, respectively. The substrates on which these layers were constructed are shown at 21, 31, and 41, respectively. The integrated circuit layer is covered with one or more layers of dielectric such as SiO₂ in which various metal conductors are constructed and connected to the circuitry by vias. To simplify the drawing, only the metal conductors that are to be connected to components on other component layers are shown in the drawing. Exemplary conductors of this type are shown at 25, 35, and 45 together with the dielectric layers that are shown at 23, 33, and 43. Dielectric layers are also typically provided on the bottom side of the substrates as shown at 34 and 44.

Connections between the various component layers are provided by vertical conductors that pass through one or more component layers. A typical vertical conductor is shown at 50. Vertical conductor 50 is constructed from component conductors shown at 51-53 by thermal diffusion bonding of the component conductors. The thermal diffusion bonding of the component conductors also bonds the various component layers together.

It should be noted that, in general, there are thousands, if not tens of thousands, of vertical conductors in a typical stacked integrated circuit. Hence, the diameters of the vias are preferably as small as possible. The minimum diameter of a via is determined by the aspect ratio permitted by the metallization process used to fill the via. Vias with aspect ratios of greater than 5 are difficult to fill reliability. Hence, it is advantageous to have the component layers be as thin as possible. In addition, thin component layers are more flexible. The flexibility improves the strength of the stacked structure and reduces cracking or other damage caused by thermal stress.

It should also be noted that it is important that the component layers be planar sheets having parallel top and bottom edges. In general, a stacked integrated circuit according to the present invention is constructed by bonding wafer-sized component layers. After all of the layers have bonded, the stacked structure is then divided into individual stacked chips. If the component layers become wedge shaped or have hills and valleys in the surface thereof due to fabrication errors, the bonding between layers will fail. In addition, the vertical vias will not be properly aligned in some areas of the chip. Hence, any economically practical wafer-stacking scheme must assure a high degree of precision over the entire wafer for each wafer component used. The manner in which the present invention provides this high degree of precision will now be discussed in detail.

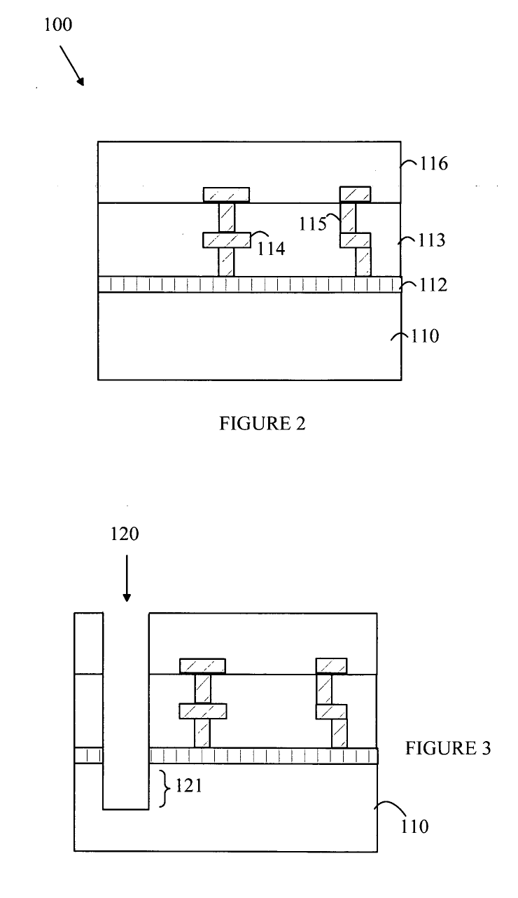

Refer now to FIG. 2, which is a cross-sectional view of a wafer 100 used as a starting point for a component layer. It will be assumed that wafer 100 has its active circuit layer 112, which is covered with a dielectric layer 113, in place. As noted above, various metal conductors are typically constructed in the dielectric layer and connected to the circuitry by metal filled vias. Typical metal conductors are shown at 114 and 115. These conductors can be divided into two classes, those that provide connections between the various components in integrated circuit layer 112 and those that are to provide connections to components in other layers of the final stacked integrated circuit. Conductor 115 is in the first class, and conductor 114 is in the second class. It will also be assumed that a second layer of dielectric 116 covers the conductors.

Refer now to FIG. 3, which is a cross-sectional view of wafer 100 after a via 120 has been etched through the dielectric layers and into substrate 110. As will be explained in more detail below, the depth 121 by which via 120 extends into substrate 110 is critical. Preferably, via 120 is etched in two steps. In the first step, the via is etched using an etchant that stops on the silicon substrate such as a fluorocarbon-based plasma etch. In the second step, the via is extended into substrate 110 by 4 to 9 microns using a timed halogen-containing gaseous plasma. It should be noted that the placement of the vias can be controlled precisely, since the wafer has fiduciary marks that are visible from the front side of the wafer, and these marks can be used to align the masks that define the via locations using conventional alignment tools.

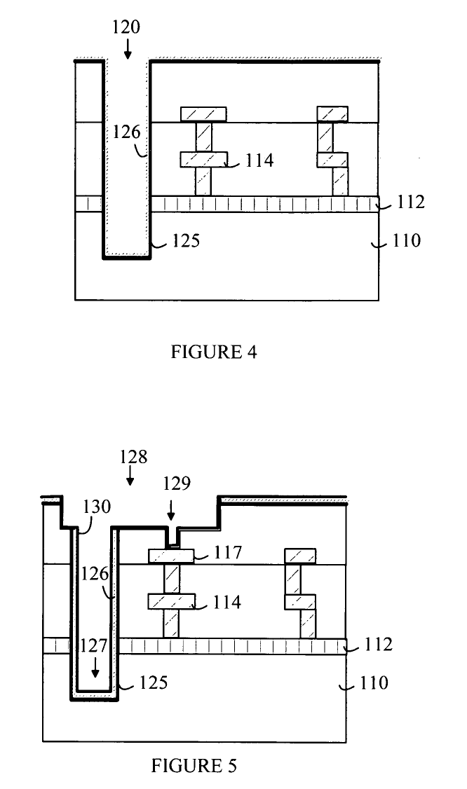

Refer now to FIG. 4, which is a cross-sectional view of wafer 100 after via 120 has been lined with two layers. Layer 125 consists of a thin dielectric layer, preferably 0.05 to 0.10 microns of SiO₂. This layer acts an electrical insulator to prevent shorting between the metal layer of the filled via and components in the integrated circuit layer 112. The second layer 126 consists of a thin layer of SiN, typically 0.05 to 0.10 microns in thickness. The SiN layer serves two functions. First, it provides a diffusion barrier that helps to prevent the metal used to fill via 120 from diffusing into the integrated circuit layer if the primary diffusion barrier discussed below fails. Second, the silicon nitride provides an etch stop for chemical etching processes used in the thinning of the silicon wafer. For example, the silicon can be thinned using a wet chemical process such as a substituted ammonium hydroxide or other alkaline chemical etch. It should also be noted that this etch stop will provide some resistance to acidic etch solutions. In this case, the silicon nitride acts as the etch stop. If a dry etch such as a Cl₂ based plasma chemistry is used to thin the silicon, the SiO₂ layer can be used as an etch stop.

Refer now to FIG. 5, which is a cross-sectional view of wafer 100 after a trench 128 has been etched in dielectric layer 116. A via 129 is opened in the bottom of trench 128 to provide contact with pad 117 that provides electrical connection to components in circuit layer 112 that are to be connected to the vertical conductor that will be formed by filling via 120 with metal. A third layer 130 is deposited in vias 127 and 129 and trench 128. Layer 130 serves two functions. First, layer 130 acts a diffusion barrier that prevents the metal used to filled the via and trench from diffusing into the remainder of the wafer. In the preferred embodiment of the present invention, the preferred metal is copper. The diffusion barrier is preferably Ta, TaN, or WN or other ternary barrier material such as TaₓSi_{y}N_{z}, W₂ Si_{y}N_{z}, etc. A 200-1000 A^{o} barrier layer is preferably deposited by a CVD or PVD process such as sputtering. Second, the portion of layer 130 at the bottom of via 129 acts as a stop in the wafer thinning process described below. Trench 128 is then filled with metal.

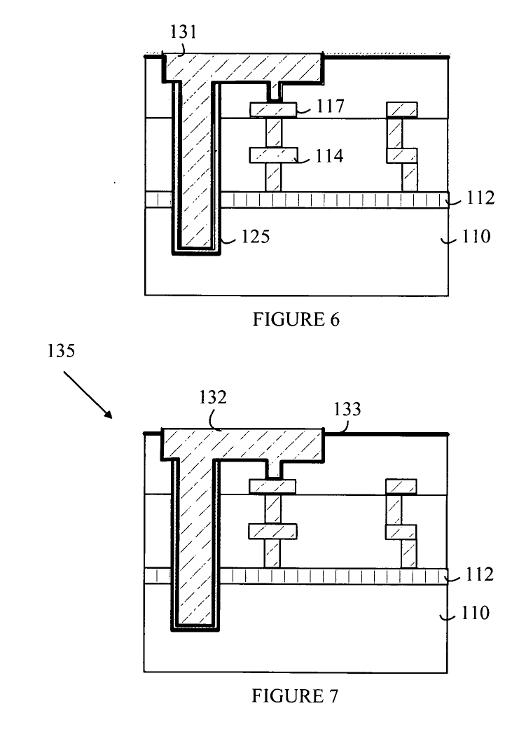

The preferred metal for the filling operation is copper. In embodiments utilizing copper, a copper seed layer is deposited in the trench and vias prior to the deposition of the copper. The seed layer can be deposited utilizing CVD or a sputtering process. The seed layer maintains the proper conduction during the subsequent electroplating process utilized to deposit the metallic copper. After the seed layer is deposited, the trench is filled with copper using electrochemical plating. The excess copper is removed by chemical mechanical polishing (CMP), leaving a copper pad 131 that is flush with the surrounding dielectric as shown in FIG. 6. In the preferred embodiment of the present invention, the final copper pad 132 is elevated relative to the surrounding dielectric layer 133 by 0.01-0.2 microns as shown in FIG. 7, which is a cross-sectional view of a completed component layer element 135. This slightly elevated pad provides improved bonding when the component layer element is bonded as described below. The elevation of the pad can be accomplished by lowering the surrounding dielectric layer or by increasing the height of the copper. The dielectric layer can be lowered by selective etching using a fluorine containing etch process. The copper height can be increased by electroless deposition of additional copper, which will occur only on the exposed copper surface.

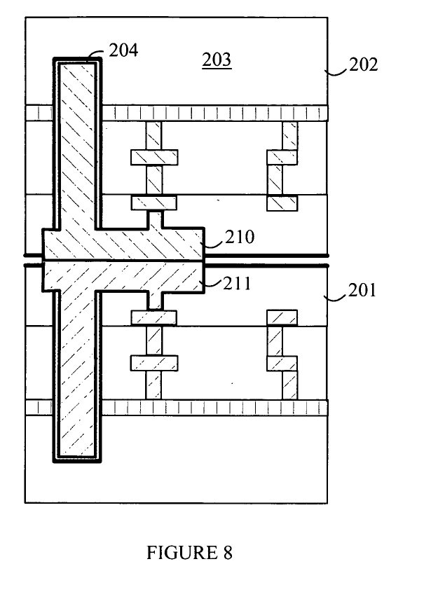

The manner in which a component layer is added to the base component layer will now be explained in more detail with reference to FIG. 8, which is a cross-sectional view of a base component layer element 202 positioned relative to a component layer element 201 that is to be bonded to element 202. The elements are positioned by turning element 201 over such that its copper bonding pads are positioned over the corresponding bonding pads on element 202. To simplify the drawing, only one pair of pads is shown at 210 and 211; however, it is to be understood that each component element may have thousands or even millions of such pads. The two component elements are pressed together and bonded using thermal diffusion bonding. The wafers are bonded by compressing the two wafers using 20-60 psi pressure at 300-450° C. temperature in a nitrogen or air atmosphere for 5-50 minutes. The wafers are positioned by utilizing fiducial marks on the front sides of the wafers. The marks on the front side of wafer 202 are viewed from the backside of the wafer. To improve the accuracy of the alignment, wafer 202 may be thinned prior to bonding.

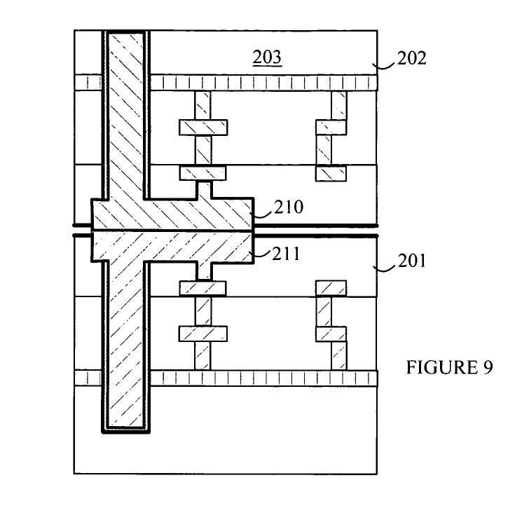

After the two elements have bonded, element 202 is thinned further to a thickness of a few microns as shown in FIG. 9 which is a cross-sectional view of the component layers after component layer element 202 has been thinned. As noted above, the resulting layer component must have parallel surfaces to assure that any subsequent element bonded to this element will be properly aligned and bonded. The present invention utilizes the portion of the diffusion/stop layer shown at 204 in the bottom of the vertical vias as a stop for this thinning process. The preferred thinning process utilizes CMP of the substrate 203. The thinning process can be a combination of grinding and CMP and/or etch processes. For example, a CMP process will remove the silicon substrate at a rate that is 100 times faster than Ta in layer 130. Hence, the CMP process will stop at the same point on each of the vias. The depth of the vias, as noted above, can be controlled to a high degree of precision. Hence, the resulting component layer will have a thickness that is tightly controlled, since it is determined by the depth of the vias.

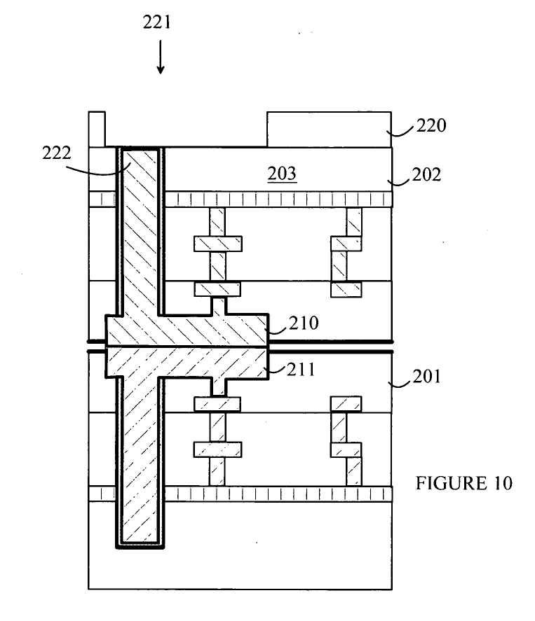

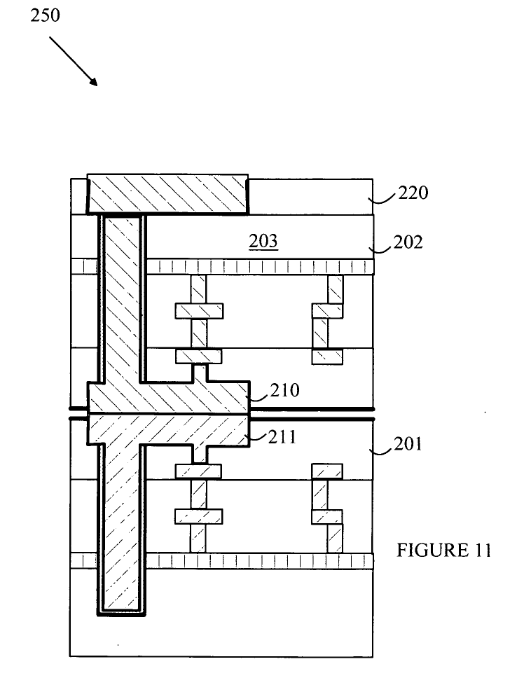

Refer now to FIG. 10. The stacking process can be continued by creating a new set of connection pads on the thinned side of the substrate in component element 202. First, an oxide layer 220 is deposited over the thinned backside of substrate 203. A trench 221 is then opened in oxide layer 220 to provide connection to the metal filled via 222. The bottoms of the metal-filled vias are easily visible from the backside of the wafer. These vias are used as alignment marks for positioning the masks used to define the trench. The trench is then lined with a diffusion barrier and filled with metal, preferably copper, as described above. If the metal used to fill the trench does not present diffusion problems, the diffusion barrier can be eliminated. The surrounding dielectric is then lowered, or additional metal added, to raise the height of the metal pad to a height slightly above the surrounding dielectric as described above.

The final two-layered device is shown in FIG. 11 at 250. Device 250 may now be used as a “base” component element on which another component element is stacked as described above. A new front-side fiducial may be generated using the vias to position the fiducial mask. Alternatively, the filled vias can be used as fiducial marks. The new component layer element is aligned with the pads of device 250 such that the corresponding pads on the new component element are in contact with the pads on device 250. The elements are then pressed together and thermally bonded as described above. After bonding, the new component element is thinned as described above and new metal pads constructed on the backside of the thinned substrate. This process may be continued with additional component elements until the desired stack thickness is obtained.

The drawings and description of the above-described embodiments of the present invention have shown only a portion of a stacked wafer structure having a single metal-filled via for making the vertical connections between the layers. However, it is to be understood that the number of such vias is very large, typically thousands or tens of thousands of vias will be present in each chip; hence, an entire wafer may have millions of such vertical connections. As noted above, these vias also determine the thickness of each component element by providing a polishing stop. Hence, the density of such vias on the wafer must be sufficient to assure that the resulting component element is flat and smooth to within the desired tolerance. In the preferred embodiment of the present invention, the distance between vias is less than 50 μM. If the density of vias created for vertical connections through the layers is not sufficient, additional vias may be added.

Various modifications to the present invention will become apparent to those skilled in the art from the foregoing description and accompanying drawings. Accordingly, the present invention is to be limited solely by the scope of the following claims.

1. An integrated circuit wafer comprising:
a wafer comprising a substrate comprising a wafer material, said substrate having first and second surfaces, said first surface having a circuit layer comprising integrated circuit elements constructed thereon;
a plurality of vias extending a first distance from said first surface of said substrate into said substrate from said first surface, said vias comprising a stop layer comprising a stop material that is more resistant to chemical/mechanical polishing (CMP) than said wafer material.

2. The integrated circuit wafer of claim 1 wherein said stop material comprises a material chosen from the group consisting of Ta, TaN, W, WN, TaₓSi_{y}N_{z}, W₂, and Si_{y}N_{z}, and wherein said wafer material comprises silicon.

3. The integrated circuit wafer of claim 1 wherein said vias are lined with a layer of an electrically insulating material.

4. The integrated circuit wafer of claim 3 wherein said electrically insulating material comprises SiO₂.

5. The integrated circuit wafer of claim 3 wherein said vias are filled with an electrically conducting material.

6. The integrated circuit wafer of claim 5 wherein said electrically conducting material comprises an element chosen from the group consisting of copper, tungsten, platinum, and titanium.

7. The integrated circuit wafer of claim 1 further comprising:
a dielectric layer having top and bottom surfaces, said dielectric layer covering said circuit layer such that said bottom surface is in contact with said integrated circuit layer; and
a plurality of electrical conductors buried in said dielectric layer and making electrical connections to said integrated circuit elements.

8. The integrated circuit wafer of claim 7 wherein at least one of said vias extends through said dielectric layer and wherein said one of said vias is filled with an electrically conducting material, said via terminating in an electrically conducting pad on said top surface of said dielectric layer.

9. The integrated circuit wafer of claim 8 wherein said electrically conducting pad extends above said top surface of said dielectric layer.

10. The integrated circuit wafer of claim 8 wherein one of said electrical conductors is connected electrically to said one of said vias.

11. A method for thinning a wafer to provide a circuit layer having a predetermined thickness, said method comprising:
providing a wafer having first and second surfaces comprising a wafer material with said circuit layer fabricated on said first surface thereof;
generating a plurality of vias, each via extending from said first surface to a first depth;
depositing a layer of a stop material in said vias, said stop material being more resistant to CMP than said wafer material; and
removing material from said second surface of said wafer utilizing CMP, said layer of stop material preventing said CMP from removing wafer material closer to said first surface than said first depth.

12. The method of claim 11 wherein said stop material comprises a material chosen from the group consisting of Ta, TaN, W, WN and wherein said wafer material comprises silicon.

13. The method of claim 11 wherein said wafer further comprises a layer of dielectric material covering said circuit layer, said dielectric layer being characterized by a thickness, and wherein said first distance and said thickness are equal to said predetermined thickness.

14. A method for adding a second circuit layer to a first wafer comprising a first circuit layer, said method comprising the steps of:
providing a plurality of bonding pads on a first surface of said first wafer;
providing a second wafer comprising a substrate of a wafer material and said second circuit layer, said second circuit layer being fabricated on a first surface of said substrate and being covered by a layer of dielectric material, said wafer further comprising a plurality of vias extending a predetermined distance from said first surface of said substrate into said substrate, said vias including a layer of stop material, said stop material being more resistant to CMP than said wafer material;
providing a plurality of bonding pads on said second wafer, there being a one to one correspondence between said bonding pads on said first and second wafers;
positioning said first and second wafers such that said bonding pads on said first wafer are brought in contact with said bonding pads on said second wafer;
causing said corresponding bonding pads to bond to one another; and
removing a portion of said second wafer by CMP of the surface of said second wafer that is not bonded to said first wafer, said stop layer in said vias determining the amount of material that is removed.

15. The method of claim 14, wherein said stop material comprises a material chosen from the group consisting of Ta, TaN, W, WN and wherein said wafer material comprises silicon.

16. The method of claim 14 further comprising the steps of:
depositing a layer of dielectric on said surface of said second wafer from which said portion was removed; and
positioning a mask with respect to said second wafer utilizing said vias as fiduciary marks.
